(19) United States
(12) Patent Application Publication
(10) Pub. No.: US 2025/0365873 A1
(43) Pub. Date: Nov. 27, 2025

(54) ELECTRICAL JUNCTION BOX

(71) Applicant: Sumitomo Wiring Systems, Ltd., Yokkaichi-Shi, Mie (JP)

(72) Inventor: Tatsuya FUJISAKA, Yokkaichi-shi, Mie (JP)

(73) Assignee: Sumitomo Wiring Systems, Ltd., Yokkaichi-Shi, Mie (JP)

(21) Appl. No.: 18/873,968

(22) PCT Filed: May 30, 2023
(86) PCT No.: PCT/JP2023/020156

§ 371 Date: Dec. 11, 2024

(30) Foreign Application Priority Data
Jun. 14, 2022 (JP) 2022-096065

(51) Int. Cl. H05K 5/02; B60L 50/60; B60R 16/023; H02G 3/08

(52) U.S. Cl. CPC H05K 5/0213; B60R 16/0239; H02G 3/081; H05K 5/0247; B60L 50/60

(57) ABSTRACT

An electrical junction box includes: a housing containing a relay that generates heat when energized; and a cover member that covers a terminal provided on one surface of the relay, and that covers a surrounding area of the terminal, wherein the cover member has a first air vent that allows airflow inside and outside of the cover member.

### CROSS-REFERENCE TO RELATED APPLICATIONS

This application is the U.S. national stage of PCT/JP2023/020156 filed on May 30, 2023, which claims priority of Japanese Patent Application No. JP 2022-096065 filed on Jun. 14, 2022, the contents of which are incorporated herein.

### TECHNICAL FIELD

The present disclosure relates to an electrical junction box containing electronic components.

### BACKGROUND

Conventionally, electrical junction boxes containing electronic components such as fuses and relays are mounted on vehicles.

An electrical junction box includes a housing. For example, the housing is composed of a first case that is open on one side and contains electronic components, and a second case that covers the open side of the first case (see JP 2016-208561A).

For example, a large current flows through an electronic component such as a relay when an electrical junction box is operated. There is a risk of electric shock when an operator's fingers touch a contact portion of the relay. Malfunctions such as electric shock can be prevented by covering the contact portion of the relay with a cover member.

Since a large current flows through the relay, heat is generated at the relay and its contact portion. In the case where the contact portion of the relay is covered with the cover member as mentioned above, the heat tends to build up inside the cover member. That is, the air inside the cover member removes the heat from the relay and its contact portion and moves, but is not released to the outside due to the cover member. This causes accumulation of hot air inside the cover member. If heat builds up inside the cover member, the cover member and the surrounding insulating resin components may wear and lose their insulation, causing malfunctions such as short circuits.

With the electrical junction box in JP 2016-208561A, such problems are not taken into consideration and cannot be solved.

The present disclosure therefore has an object of providing an electrical junction box that can prevent heat from a contact portion of an electronic component from building up while covering the contact portion to prevent the contact portion from being exposed.

### SUMMARY OF INVENTION

An electrical junction box according to an embodiment of the present disclosure is an electrical junction box including: a housing containing an electronic component that generates heat when energized; and a cover member that covers a terminal provided on a side surface of the electronic component, and that covers a surrounding area of the terminal, wherein the cover member has an air vent that allows airflow inside and outside of the cover member.

### Advantageous Effects

According to the present disclosure, it is possible to prevent heat from a contact portion of an electronic component from building up while covering the contact portion to prevent the contact portion from being exposed.

### BRIEF DESCRIPTION OF DRAWINGS

FIG. 1 is s perspective view of an electrical junction box according to Embodiment 1.

FIG. 2A is a plan view of the electrical junction box according to Embodiment 1.

FIG. 2B is a side view of the electrical junction box according to Embodiment 1.

FIG. 3 is a partially enlarged perspective view showing a state in which a cover member is attached in the electrical junction box according to Embodiment 1.

FIG. 4 is a partially enlarged perspective view showing a state in which the cover member is removed in the electrical junction box according to Embodiment 1.

FIG. 5 is a schematic vertical sectional view of a clamping mechanism in a state in which the cover member is attached in the electrical junction box according to Embodiment 1.

FIG. 6 is a sectional view taken along arrow VI in FIG. 5.

FIG. 7 is a schematic vertical sectional view of the clamping mechanism in a state in which the cover member is removed in the electrical junction box according to Embodiment 1.

FIG. 8 is a schematic vertical sectional view of the electrical junction box according to Embodiment 1 with the cover member and a rectangular plate portion of a mounting seat omitted.

FIG. 9A is a perspective view showing the front side of the cover member of the electrical junction box according to Embodiment 1.

FIG. 9B is a perspective view showing the back side of the cover member of the electrical junction box according to Embodiment 1.

FIG. 10 is a perspective view showing a cover member of an electrical junction box according to Embodiment 2.

FIG. 11 is a perspective view showing a cover member of an electrical junction box according to Embodiment 3.

FIG. 12 is a perspective view showing a cover member of an electrical junction box according to Embodiment 4.

### DETAILED DESCRIPTION OF PREFERRED EMBODIMENTS

First, embodiments of the present disclosure will be listed and described. The embodiments described below may be at least partly combined in any way.

An electrical junction box according to an embodiment of the present disclosure is an electrical junction box including: a housing containing an electronic component that generates heat when energized; and a cover member that covers a terminal provided on a side surface of the electronic component, and that covers a surrounding area of the terminal, wherein the cover member has an air vent that allows airflow inside and outside of the cover member.

In this embodiment, the cover member covers the terminal provided on the side surface of the electronic component and its surrounding area, and the air vent of the cover member allows airflow inside and outside of the cover member. Thus, heat from the contact portion of the electronic component can be prevented from building up inside the cover member while the contact portion is covered and prevented from being exposed.

In the electrical junction box according to an embodiment of the present disclosure, the electronic component is mounted on a pedestal provided in the housing, the cover member includes a facing plate that faces the side surface of the electronic component, and an electric shock prevention plate that is provided at an edge of the facing plate located apart from the housing and shields a gap between the facing plate and the side surface to prevent electric shock, and the air vent includes a first air vent formed in the electric shock prevention plate.

In this embodiment, the electric shock prevention plate shields the gap between the facing plate of the cover member and the side surface of the electronic component to prevent electric shock, and the first air vent formed in the electric shock prevention plate allows airflow inside and outside of the cover member. Thus, heat from the contact portion of the electronic component can be prevented from building up inside the cover member while the contact portion is covered to prevent electric shock due to exposure of the contact portion.

In the electrical junction box according to an embodiment of the present disclosure, the first air vent is formed at one edge of the electric shock prevention plate closer to the side surface of the electronic component.

In this embodiment, the first air vent is formed at one edge closer to the side surface of the electronic component. In other words, the first air vent is formed above the contact portion of the electronic component, that is, in the path of rising air that has absorbed heat from the contact portion and become hot. Hence, hot air is quickly released to the outside of the cover member, and heat from the contact portion can be prevented from building up inside the cover member.

In the electrical junction box according to an embodiment of the present disclosure, the air vent includes a second air vent formed in the electric shock prevention plate apart from the one edge.

In this embodiment, the second air vent is formed in the electric shock prevention plate at a position located apart from the one edge, in addition to the first air vent. Hence, hot air inside the cover member is more quickly released to the outside of the cover member, and heat from the contact portion can be more effectively prevented from building up inside the cover member.

In the electrical junction box according to an embodiment of the present disclosure, the first air vent has a comb shape that is open toward another edge opposite to the one edge.

In this embodiment, the first air vent has a comb shape that is open toward the other edge opposite to the one edge. Thus, the air vent for releasing hot air inside the cover member to the outside of the cover member is expanded while ensuring that electric shock due to exposure of the contact portion of the electronic component is prevented.

In the electrical junction box according to an embodiment of the present disclosure, the air vent includes a third air vent formed in the facing plate.

In this embodiment, the third air vent is formed in the facing plate of the cover member, and therefore outside air flows into the cover member through the third air vent. This shortens the circulation of air inside and outside the cover member, making it possible to increase the efficiency of heat dissipation by releasing hot air inside the cover member to the outside.

In the electrical junction box according to an embodiment of the present disclosure, the pedestal includes a clamping mechanism that clamps the facing plate, and the facing plate has an engagement protrusion that engages with an engagement portion formed in the clamping mechanism.

In this embodiment, when the cover member is attached, the clamping mechanism clamps the facing plate of the cover member, and the engagement protrusion of the facing plate engages with the engagement portion of the clamping mechanism. This prevents the cover member from being unintentionally removed.

Electrical junction boxes according to embodiments of the present disclosure will be described below, with reference to the drawings. The present disclosure is not limited to these examples, but is defined by the claims and intended to include all modifications within the meaning and scope equivalent to the claims.

### Embodiment 1

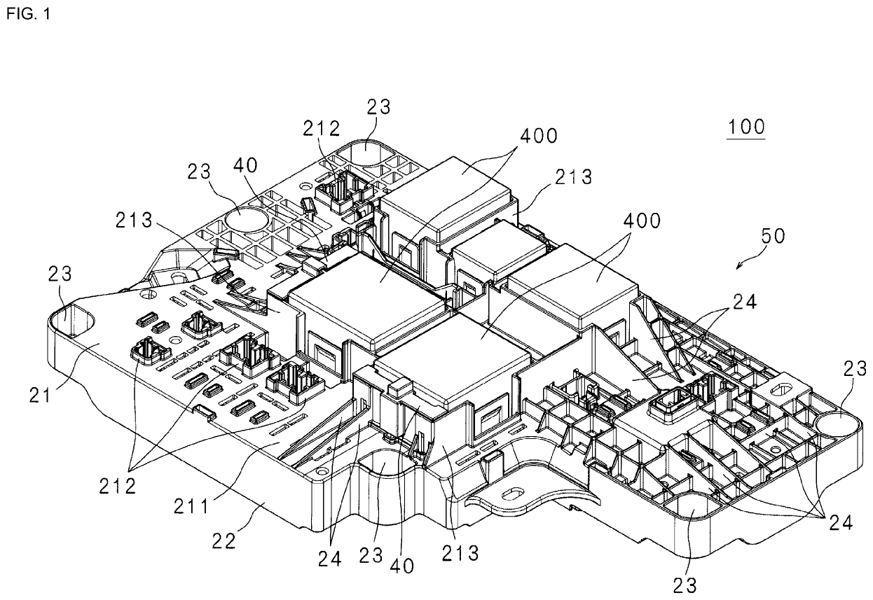

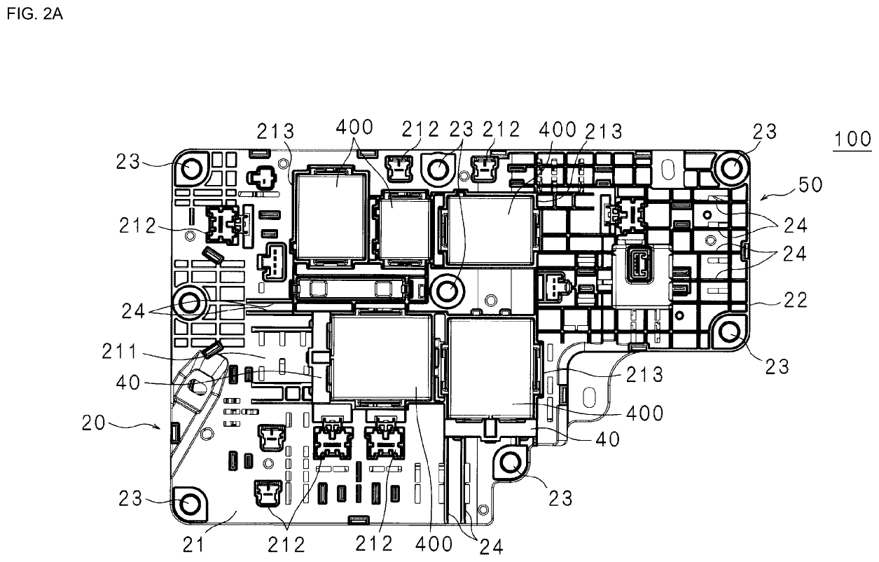

FIG. 1 is a perspective view of an electrical junction box 100 according to Embodiment 1. FIGS. 2A and 2B are a plan view and a side view of the electrical junction box 100 according to Embodiment 1. FIG. 2A is a plan view of the electrical junction box 100, and FIG. 2B is a side view of the electrical junction box 100.

The electrical junction box 100 is attached to the outside of an attachment object, such as a battery pack 200 (see FIGS. 2A and 2B) of an electric vehicle (EV). FIG. 2B shows the electrical junction box 100 attached to the battery pack 200, for the sake of convenience.

The electrical junction box 100 includes a housing 50 containing fuses, substrates, and the like. The housing 50 is flat and approximately rectangular in plan view, with one corner of one end in the length direction cut out in a stepped shape. The housing 50 is made of, for example, resin, and includes a lower case 30 that is attached to the attachment object and an upper case 20 that covers the lower case 30. In the following description, it is assumed that the upper case 20 side is the upper side and the lower case 30 side is the lower side, for the sake of convenience.

The lower case 30 has a box shape that is open on the upper case 20 side. The upper case 20 has a box shape that is open on the lower case 30 side. The upper case 20 is slightly larger than the lower case 30 in the length direction and in the width direction orthogonal to the length direction, and covers the lower case 30.

The lower case 30 has a bottom wall 31 whose outer surface comes into contact with the attachment object, and a side wall 33 that extends vertically from the edges of the bottom wall 31 to the upper case 20 side.

The upper case 20 has a ceiling wall 21 that faces the bottom wall 31 of the lower case 30, and a side wall 22 that is provided along the edges of the ceiling wall 21 and extends vertically to the lower case 30 side. The upper case 20 is provided with fastening portions 23 for attaching the housing 50 to the attachment object, at both ends and at an intermediate portion in the length direction.

That is, fastening portions 23 are provided at both corners of one end in the length direction, and at both corners and between the corners of the other end in the length direction. Further, at an intermediate portion of the upper case 20 in the length direction, three fastening portions 23 are arranged in the width direction. Each fastening portion 23 protrudes from the inner surface of the ceiling wall 21 facing the bottom wall 31. The fastening portions 23 except for one fastening portion 23 located approximately at the center of the ceiling wall 21 are located near the side wall 22 (see FIG. 2A).

Each fastening portion 23 has a bottomed cylindrical shape and is open on the ceiling wall 21 side. A through hole (not shown) used when attaching the housing 50 to the attachment object is formed at the bottom of each fastening portion 23. The housing 50 (electrical junction box 100) can be attached to the attachment object by inserting a screw from the attachment object into the through hole of each fastening portion 23 and screwing it into a nut (not shown) provided in the fastening portion 23.

A plurality of ribs 24 protrude from the outer surface 211 of the ceiling wall 21 opposite to the inner surface, in order to prevent warping of the ceiling wall 21 due to gravity, differences in thermal expansion, and the like.

Moreover, various connection portions 212 for connection to other devices are arranged at a plurality of locations on the outer surface 211 of the ceiling wall 21. Further, at approximately the center of the outer surface 211 of the ceiling wall 21, a plurality of mounting seats 213 (pedestals) for relays 400 (electronic components) are arranged and the relays 400 are mounted on the respective mounting seats 213.

Each relay 400 is connected to a bus bar 500 (described later). The contact portion between the bus bar 500 and the relay 400 is covered with a cover member 40.

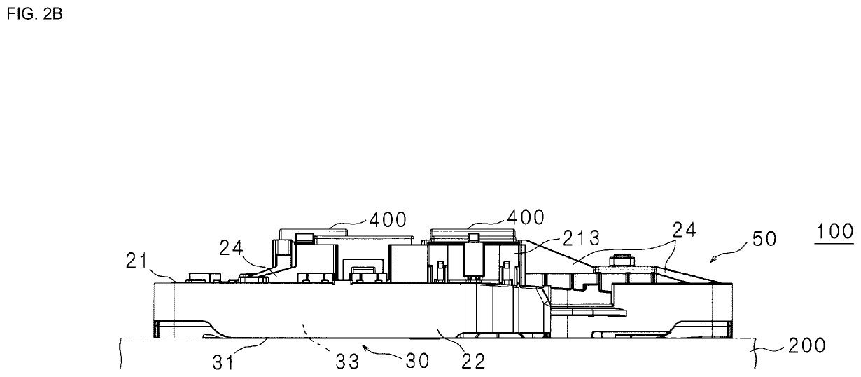

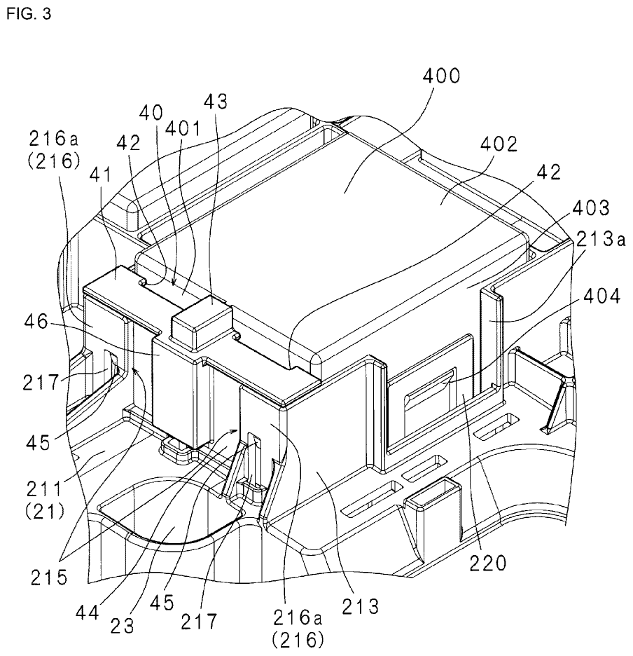

FIG. 3 is a partially enlarged perspective view showing a state in which the cover member 40 is attached in the electrical junction box 100 according to Embodiment 1. FIG. 4 is a partially enlarged perspective view showing a state in which the cover member 40 is removed in the electrical junction box 100 according to Embodiment 1.

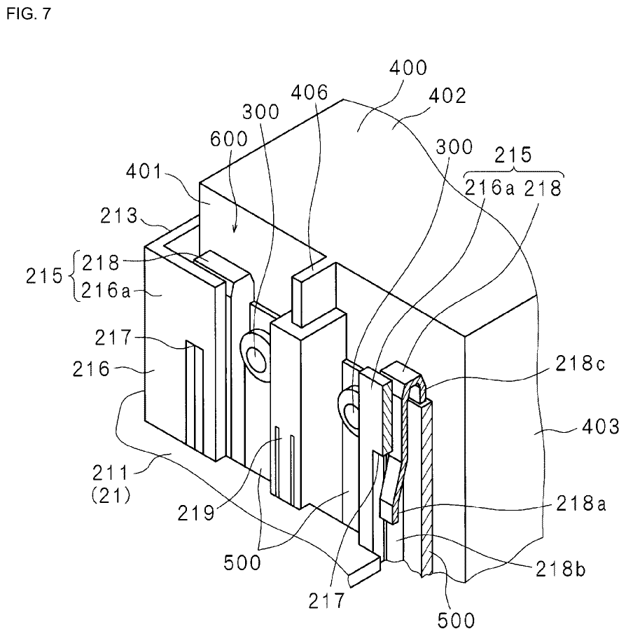

The mounting seat 213 is a recess that is rectangular in plan view. That is, in the mounting seat 213, a plate material stands upward from each edge of the rectangular bottom surface 221 (see FIG. 8). The relay 400 has a rectangular parallelepiped shape, and is mounted on the mounting seat 213 from the bottom side, with the upper surface 402 exposed. The cover member 40 is attached between the relay 400 and the mounting seat 213.

The relay 400 has two terminals 405 laterally spaced apart from each other, on one surface 401 (side surface). The bus bar 500 is connected to each terminal 405. Each terminal 405 is cylindrical with a threaded portion formed on the inner circumferential surface, and only one end is exposed from the one surface 401 and the remaining part is embedded in the relay 400. The bus bar 500 is screwed to the terminal 405 by inserting a bolt 300 through a through hole formed at one end of the bus bar 500 and screwing the bolt 300 to the terminal 405. A strip-shaped shielding plate 406 extending vertically protrudes from the center of the one surface 401 between the two terminals 405.

The relay 400 also has an engagement protrusion 404 that engages with an engaged portion 220 (described later) of the mounting seat 213, on a side surface 403 adjacent to the one surface 401.

The mounting seat 213 has a rectangular plate portion 216 facing the one surface 401 of the relay 400. The rectangular plate portion 216 has a cutout in an intermediate portion corresponding to the terminals 405 of the relay 400, excluding both ends 216a in the lateral direction. An engagement groove 219 is provided between both ends 216a at a position corresponding to the shielding plate 406 of the relay 400. The inside of the engagement groove 219 corresponds in shape to the shielding plate 406, and engages with the shielding plate 406. The engagement groove 219 is shorter than the shielding plate 406 in the vertical direction, with both ends open. Therefore, the upper end of the shielding plate 406 sticks out of the upper end of the engagement groove 219 (see FIG. 4).

Each end 216a of the rectangular plate portion 216 has a notch 217 (engagement portion) that engages with an engagement protrusion 45 (described later) of the cover member 40. The notch 217 is a rectangle extending vertically. The end 216a forms a clamping mechanism 215 together with a clamping pillar 218. The clamping pillar 218 and the clamping mechanism 215 will be described in detail later.

In the mounting seat 213, an open portion 213a is provided in an intermediate portion in the lateral direction of the plate portion adjacent to the rectangular plate portion 216. The open portion 213a is provided with the engaged portion 220 that engages with the engagement protrusion 404 of the relay 400. The engaged portion 220 has an inverted U-shape. The engagement between the engaged portion 220 and the engagement protrusion 404 causes the relay 400 to be held on the mounting seat 213.

In the mounting seat 213, the clamping mechanisms 215 for clamping the cover member 40 are provided at both ends of the rectangular plate portion 216. Each clamping mechanism 215 is composed of the end 216a of the rectangular plate portion 216 and the clamping pillar 218, as mentioned above. The two clamping pillars 218 have the same shape.

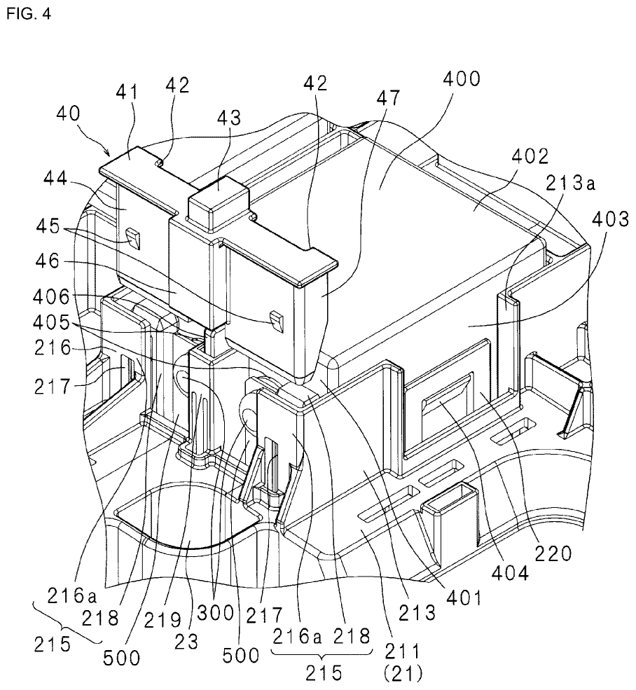

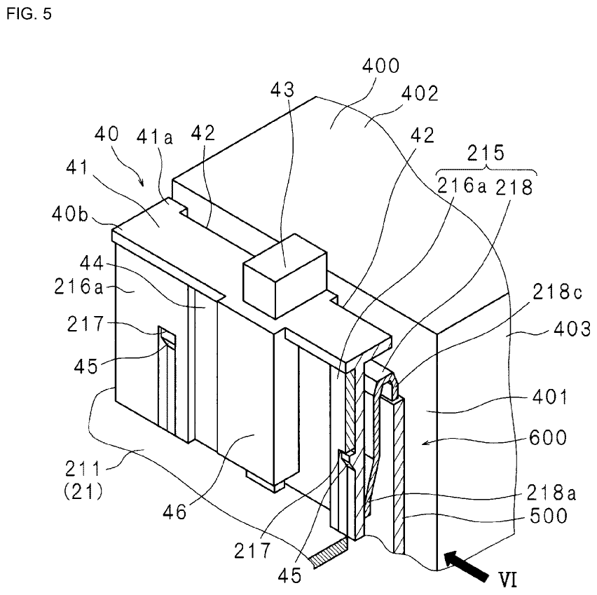

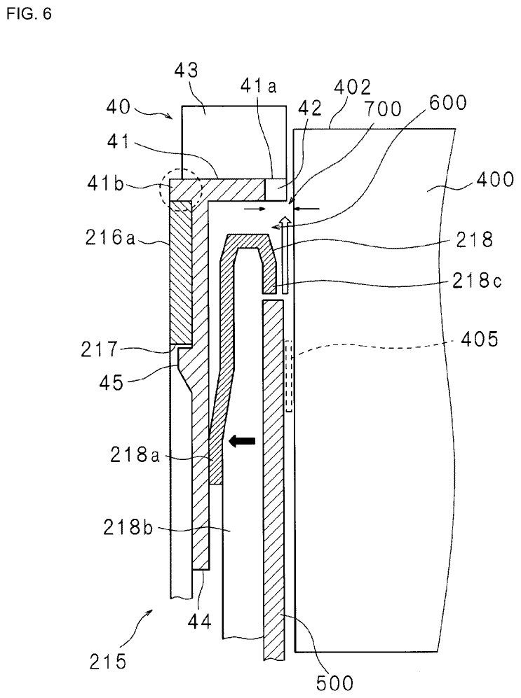

FIG. 5 is a schematic vertical sectional view of the clamping mechanism 215 in a state in which the cover member 40 is attached in the electrical junction box 100 according to Embodiment 1. FIG. 6 is a sectional view taken along arrow FIG. 7 is a schematic vertical sectional view of the clamping VI in FIG. 5. mechanism 215 in a state in which the cover member 40 is removed in the electrical junction box 100 according to Embodiment 1. FIG. 8 is a schematic vertical sectional view of the electrical junction box 100 according to Embodiment 1 with the cover member 40 and the rectangular plate portion 216 of the mounting seat 213 omitted. FIG. 8 shows the state in which the bolt 300 and the bus bar 500 are removed, for the sake of convenience.

Each clamping pillar 218 protrudes from the bottom surface 221 of the mounting seat 213, on the inner side of the corresponding end 216a and apart from the end 216a (see FIG. 8). Each clamping pillar 218 is a flat rectangular parallelepiped housing extending vertically, and is open on the bottom surface 221 side.

Both main surfaces of the clamping pillar 218 face the end 216a and the relay 400. Of the two main surfaces, one main surface on the relay 400 side is open, with an upper end 218c provided at the top. The one end of the bus bar 500 is inserted between the clamping pillar 218 and the one surface 401 of the relay 400 from below and is positioned by the upper end 218c (see FIG. 6).

The other main surface of the clamping pillar 218 has a biasing portion 218a raised by making a cut along each side wall 218b near the side wall 218b. The biasing portion 218a is shorter than the side wall 218b on the lower side, and has the lower end protruding to the end 216a side. As shown in FIG. 7, the biasing portion 218a is located at a position corresponding to the notch 217 of the end 216a.

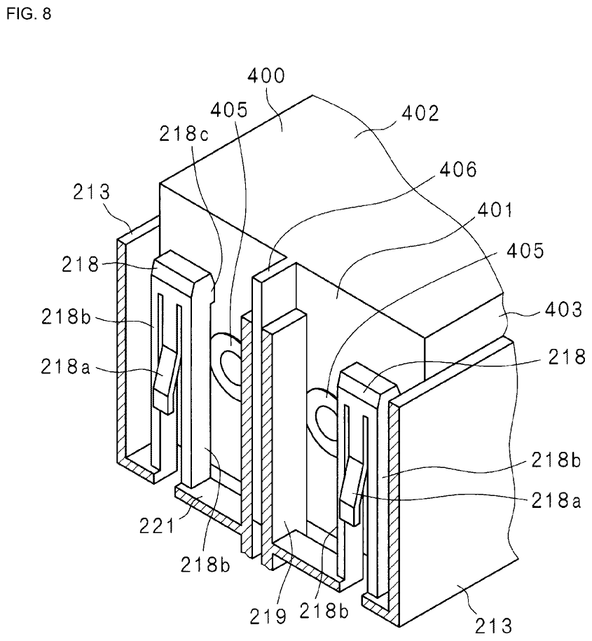

FIGS. 9A and 9B are perspective views showing the cover member 40 of the electrical junction box 100 according to Embodiment 1. FIG. 9A is a perspective view showing the front side of the cover member 40. FIG. 9B is a perspective view showing the back side of the cover member 40. The cover member 40 is made of, for example, an insulating material, and covers the contact portion on the one surface 401 of the relay 400 as mentioned above. That is, the cover member 40 covers approximately the entire one surface 401, including each terminal 405 (bolt 300) of the relay 400 and one end of the bus bar 500 connected to the terminal 405.

The cover member 40 has a facing plate 44 that is apart from and faces the one surface 401 in the attached state. The facing plate 44 is rectangular. In the attached state, the facing plate 44 is interposed between the end 216a and the clamping pillar 218 such that both long sides will face each other in the vertical direction, and is clamped by the end 216a and the clamping pillar 218.

The facing plate 44 has, on the front surface, two engagement protrusions 45 that engage with the notches 217 of the respective ends 216a as mentioned above. The facing plate 44 also has an intermediate portion 46 in the lateral direction protruding outward. The intermediate portion 46 is approximately C-shaped in cross-section, and the engagement groove 219 is stored inside the intermediate portion 46 in the attached state of the cover member 40.

Side walls 47 extend from both ends of the facing plate 44 in the longitudinal direction (lateral direction) toward the relay 400 (see FIG. 4). Each side wall 47 is approximately a rectangle extending vertically. A part closer to the lower end of the side wall 47 is smaller in dimension in the direction in which the facing plate 44 and the one surface 401 face each other (hereafter simply referred to as the facing direction).

An upper edge plate 41 (electric shock prevention plate) extends to the relay 400 side from the upper edge of the facing plate 44, that is, the edge of the facing plate 44 that is separate from the housing 50. The upper edge plate 41 is a rectangle extending along the upper edge of the facing plate 44. The upper edge plate 41 shields the gap 600 between the facing plate 44 and the one surface 401 of the relay 400. The upper edge plate 41 is larger in dimension than the gap 600 in the facing direction. The upper edge plate 41 is larger in dimension than the facing plate 44 in the lateral direction.

Hence, in the attached state of the cover member 40, the other edge 41b of the upper edge plate 41 opposite to one edge 41a located closer to the one surface 401 protrudes outward beyond the facing plate 44. In addition, both ends of the upper edge plate 41 in the longitudinal direction protrude outward beyond the side walls 47.

The upper edge plate 41 has a projection 43 protruding from the intermediate portion in the longitudinal direction. The projection 43 is open on the one surface 401 side, and is approximately C-shaped in cross section. In the attached state of the cover member 40, the upper end of the shielding plate 406 is stored inside the projection 43.

The upper edge plate 41 also has a first air vent 42 that allows airflow inside and outside of the cover member 40. The first air vent 42 is provided at the one edge 41a. That is, the first air vent 42 is formed by cutting out the intermediate portion of the one edge 41a along the one edge 41a. The first air vent 42 is an elongated rectangle, and is provided on both sides of the projection 43 in the upper edge plate 41. Each first air vent 42 is located directly above the corresponding terminal 405. A distance 700 (see FIG. 6) between the first air vent 42 and the one surface 401 of the relay 400 in the facing direction is 2 mm to 4 mm, for example.

The following will describe attaching the relay 400 in the electrical junction box 100 according to Embodiment 1.

The operator inserts the cover member 40 (facing plate 44) between the end 216a and the clamping pillar 218 from the lower end of the facing plate 44. When the facing plate 44 moves between the end 216a and the clamping pillar 218, the biasing portion 218a of the clamping pillar 218 presses the facing plate 44 toward the end 216a (see the solid arrow in FIG. 6). Accordingly, the facing plate 44 moves downward while in contact with the inner surface of the end 216a. That is, the engagement protrusion 45 on the front side of the facing plate 44 moves while in contact with the end 216a, and when the engagement protrusion 45 reaches the position of the notch 217 of the end 216a, the engagement protrusion 45 enters the notch 217 and engages with the notch 217 as shown in FIGS. 5 and 6.

When the engagement protrusion 45 and the notch 217 engage with each other, the lower surface of the other edge 41b of the upper edge plate 41 comes into contact with the upper end surface of the end 216a (see the dashed circle in FIG. 6). Here, each of the lower surfaces of both ends of the upper edge plate 41 in the longitudinal direction also comes into contact with the upper end surface of the plate portion adjacent to the rectangular plate portion 216 (end 216a) (see FIG. 3).

As a result, the facing plate 44 is clamped and held by the clamping mechanism 215 (end 216a and clamping pillar 218). That is, the engagement between the engagement protrusion 45 and the notch 217 prevents the cover member 40 from moving upward, and the contact between the lower surface of the other edge 41b and the upper end surface of the end 216a prevents the cover member 40 from moving downward. Both ends of the facing plate 44 in the lateral direction are clamped by the respective clamping mechanisms 215.

When removing the cover member 40, the operator presses the engagement protrusion 45 to the one surface 401 side of the relay 400 to disengage the engagement protrusion 45 and the notch 217, and then pulls out the cover member 40 upward from between the end 216a and the clamping pillar 218.

During energization, a large current flows through the relay 400, and therefore there is a risk of electric shock if the operator's fingers touch the terminal 405. The electrical junction box 100 according to Embodiment 1 includes the cover member 40, and the cover member 40 covers the gap 600 between the facing plate 44 and the one surface 401 of the relay 400, as described above. This prevents fingertips from entering the gap 600 and causing malfunctions such as electric shock.

Since a large current flows through the relay 400 as mentioned above, heat is generated at the relay 400 and the contact portion of the relay 400 (the contact portion of the terminal 405 and the bus bar 500). The air inside the cover member 40 removes the heat from the relay 400 and the contact portion of the relay 400 and rises (see the white arrow in FIG. 6).

Here, in the case where the cover member 40 shields the gap 600, the air that has absorbed the heat generated at the relay 400 and the contact portion of the relay 400 and become hot is not released to the outside of the cover member 40 and the heat tends to build up inside the cover member 40. If the heat builds up inside the cover member 40, the cover member 40 and the resin components surrounding the cover member 40 may wear and lose their insulation, causing malfunctions such as short circuits.

In the electrical junction box 100 according to Embodiment 1, the cover member 40 has the first air vent 42, and therefore it is possible to allow airflow inside and outside of the cover member 40. Such airflow enables the heat generated at the relay 400 and the contact portion of the relay 400 to be released to the outside of the cover member 40 without building up inside the cover member 40. Consequently, malfunctions caused by heat building up inside the cover member 40 can be prevented.

Moreover, in the electrical junction box 100 according to Embodiment 1, the first air vent 42 is located directly above the contact portion (terminal 405) of the relay 400, as described above. That is, the first air vent 42 is located in the path of movement of the hot air. The first air vent 42 can thus quickly release the hot air to the outside of the cover member 40.

Moreover, since the distance 700 between the first air vent 42 and the one surface 401 of the relay 400 is 2 mm to 4 mm, human fingertips are kept from entering the gap 600 from the first air vent 42. This ensures the foregoing electric shock prevention effect while allowing airflow inside and outside of the cover member 40.

Thus, the electrical junction box 100 according to Embodiment 1 can prevent both malfunctions caused by exposure of the contact portion of the relay 400 and malfunctions caused by heat buildup inside the cover member 40.

Although the above describes an example in which the first air vent 42 is provided at the one edge 41a, the present disclosure is not limited to this. The same effect as above can be achieved as long as the first air vent 42 is provided in the upper edge plate 41.

Although the above describes an example in which one first air vent 42 is provided on each side of the projection 43 of the upper edge plate 41, the present disclosure is not limited to this.

The first air vent 42 may be provided at each of a plurality of locations on each side of the projection 43.

### Embodiment 2

In the electrical junction box 100 according to Embodiment 1, the air vent is provided only at one edge 41a of the upper edge plate 41. In the electrical junction box 100 according to Embodiment 2, the air vent is also provided at a location other than the one edge 41a of the upper edge plate 41.

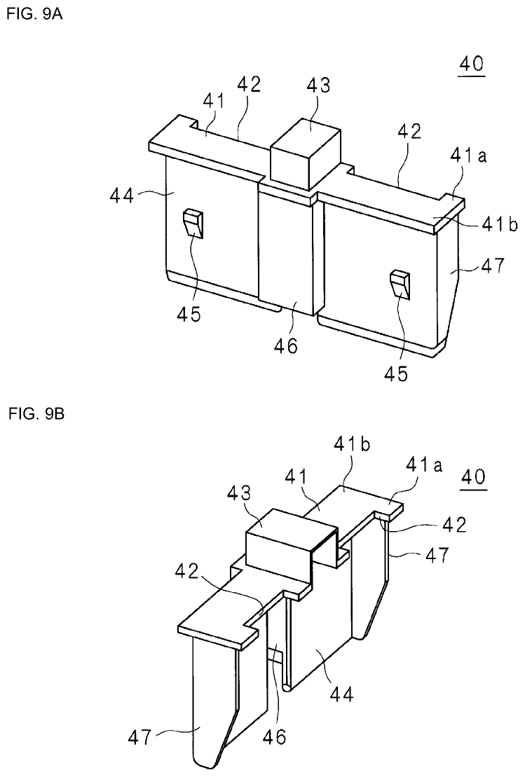

FIG. 10 is a perspective view showing the cover member 40 of the electrical junction box 100 according to Embodiment 2.

In the electrical junction box 100 according to Embodiment 2, the first air vent 42 is located at the one edge 41a of the upper edge plate 41 at a position directly above each terminal 405 (see FIG. 6), as in Embodiment 1. In the electrical junction box 100 according to Embodiment 2, the cover member 40 further has a second air vent 48 in the upper edge plate 41.

The second air vent 48 is a circular through hole formed through the upper

edge plate 41, and is located apart from the one edge 41a. Three second air vents 48 are formed on each side of the projection 43 in the upper edge plate 41. The three second air vents 48 are formed in the upper edge plate 41 between the one edge 41a and the other edge 41b, and are spaced apart from each other in the longitudinal direction of the upper edge plate 41.

As described above, in the electrical junction box 100 according to Embodiment 2, the first air vent 42 is located at the one edge 41a of the upper edge plate 41 at a position directly above each terminal 405. Hence, the heat generated at the relay 400 and the contact portion of the relay 400 is quickly released to the outside of the cover member 40 without building up inside the cover member 40, and therefore malfunctions caused by heat building up inside the cover member 40 can be prevented, as in Embodiment 1.

The electrical junction box 100 according to Embodiment 2 further has the second air vent 48 in the upper edge plate 41 in addition to the first air vent 42, as described above. Therefore, the heat generated at the relay 400 and the contact portion of the relay 400 can be more quickly released to the outside of the cover member 40 through the first air vent 42 and the second air vent 48.

Although the above describes an example in which the second air vent 48 is a circular through hole, the present disclosure is not limited to this. The second air vent 48 may be, for example, triangular, rectangular, oval, or oblong.

Although the above describes an example in which three second air vents 48 are formed on each side of the projection 43 in the upper edge plate 41, the present disclosure is not limited to this. The number of second air vents 48 may be more than three or less than three.

The same parts as those in Embodiment 1 are given the same reference signs and their detailed description is omitted.

### Embodiment 3

In the electrical junction box 100 according to Embodiment 1, the air vent is provided only in the upper edge plate 41. In the electrical junction box 100 according to Embodiment 3, the air vent is also provided at a location other than the upper edge plate 41.

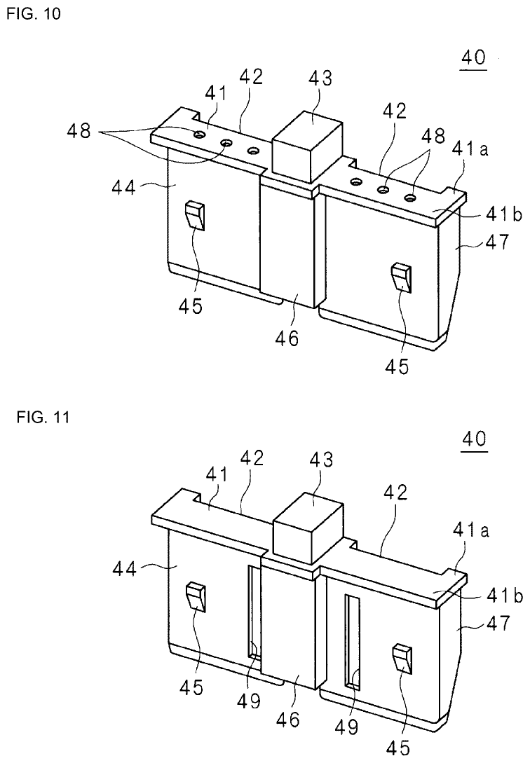

FIG. 11 is a perspective view showing the cover member 40 of the electrical junction box 100 according to Embodiment 3.

In the electrical junction box 100 according to Embodiment 3, the first air vent 42 is located at the one edge 41a of the upper edge plate 41 at a position directly above each terminal 405, as in Embodiment 1. In the electrical junction box 100 according to Embodiment 3, the cover member 40 further has a third air vent 49 in the facing plate 44.

The third air vent 49 is a slit-shaped through hole formed through the facing plate 44, and extends vertically. One third air vent 49 is formed on each side of the intermediate portion 46 in the facing plate 44. Each third air vent 49 is located in the facing plate 44 between the intermediate portion 46 and the engagement protrusion 45 and closer to the intermediate portion 46. The dimension of the third air vent 49 in the lateral direction (hereafter referred to as the width) is approximately 2 mm to 4 mm.

As described above, in the electrical junction box 100 according to Embodiment 3, the first air vent 42 is located at the one edge 41a of the upper edge plate 41 at a position directly above each terminal 405. Hence, the heat generated at the relay 400 and the contact portion of the relay 400 is quickly released to the outside of the cover member 40 without building up inside the cover member 40, and therefore malfunctions caused by heat building up inside the cover member 40 can be prevented, as in Embodiment 1.

The electrical junction box 100 according to Embodiment 3 further has the third air vent 49 in the facing plate 44 in addition to the first air vent 42, as described above. The outside air easily flows into the cover member 40 through the third air vent 49, absorbs heat from the relay 400 and the contact portion of the relay 400 and rises, and is released to the outside of the cover member 40 through the first air vent 42. Therefore, in the electrical junction box 100 according to Embodiment 3, the circulation of air inside and outside the cover member 40 is shorter than in the case where the facing plate 44 does not have the third air vent 49, and thus the efficiency of heat dissipation can be enhanced.

In the electrical junction box 100 according to Embodiment 3, since the width of the third air vent 49 is 2 mm to 4 mm as described above, human fingertips are kept from entering the gap 600 from the third air vent 49. The third air vent 49 can thus prevent human fingers from touching the terminal 405 (bolt 300) of the relay 400 or the bus bar 500 while allowing airflow inside and outside of the cover member 40.

Although the above describes an example in which the third air vent 49 is slit-shaped, the present disclosure is not limited to this. The third air vent 49 may be, for example, triangular, rectangular, or oval.

Although the above describes an example in which one third air vent 49 is formed on each side of the intermediate portion 46 in the facing plate 44, the present disclosure is not limited to this. For example, a plurality of third air vents 49 may be formed on each side of the intermediate portion 46.

Although the above describes an example in which the third air vent 49 is located between the intermediate portion 46 and the engagement protrusion 45 and closer to the intermediate portion 46, the present disclosure is not limited to this. The third air vent 49 is located at any position that does not overlap with the end 216a of the mounting seat 213 and is not hidden by the end 216a when the cover member 40 is attached.

The same parts as those in Embodiment 1 are given the same reference signs and their detailed description is omitted.

### Embodiment 4

In the electrical junction box 100 according to Embodiment 1, the first air vent 42 is rectangular. The electrical junction box 100 according to Embodiment 4 has a first air vent 42A different in shape from the first air vent 42.

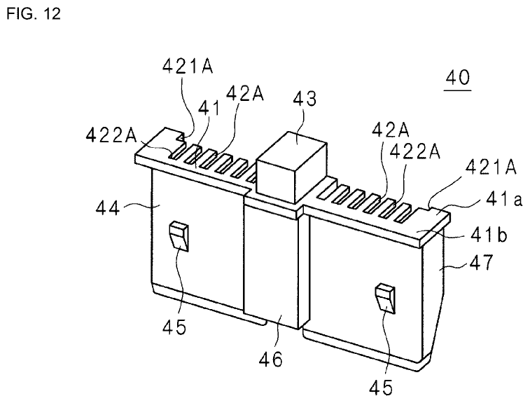

FIG. 12 is a perspective view showing the cover member 40 of the electrical junction box 100 according to Embodiment 4.

In the electrical junction box 100 according to Embodiment 4, the cover member 40 has the first air vent 42A. The first air vent 42A is provided at the same position as the first air vent 42 in Embodiment 1, that is, at the one edge 41a of the upper edge plate 41 and directly above the terminal 405, and is formed through the upper edge plate 41. The first air vent 42A is formed on each side of the projection 43 in the upper edge plate 41.

Each first air vent 42A differs in shape from the first air vent 42 in Embodiment 1. Each first air vent 42A has a comb shape that is open toward the other edge 41b. That is, each first air vent 42A has a comb base portion 421A formed by cutting out the intermediate portion of the one edge 41a in the length direction along the one edge 41a into an elongated rectangle, and elongated comb tooth portions 422A extending from the comb base portion 421A toward the other edge 41b. The comb base portion 421A has the same shape as the first air vent 42 in the electrical junction box 100 according to Embodiment 1. The comb tooth portions 422A are arranged at a plurality of locations with certain intervals in the longitudinal direction of the comb base portion 421A. The dimension of each comb tooth portion 422A in the arrangement direction (hereafter referred to as the width) is approximately 2 mm to 4 mm.

As described above, in the electrical junction box 100 according to Embodiment 4, the first air vent 42A is located at the one edge 41a of the upper edge plate 41 at a position directly above each terminal 405. Hence, the heat generated at the relay 400 and the contact portion of the relay 400 is quickly released to the outside of the cover member 40 without building up inside the cover member 40, and therefore malfunctions caused by heat building up inside the cover member 40 can be prevented.

Moreover, in the electrical junction box 100 according to Embodiment 4, the first air vent 42A has a comb shape that is open toward the other edge 41b as described above. In other words, in the electrical junction box 100 according to Embodiment 4, the plurality of comb tooth portions 422A are formed in the upper edge plate 41 in addition to the comb base portion 421A corresponding to the first air vent 42 in Embodiment 1. Therefore, the heat generated at the relay 400 and the contact portion of the relay 400 can be more quickly released to the outside of the cover member 40 through the comb base portion 421A and the comb tooth portions 422A.

In the electrical junction box 100 according to Embodiment 4, since the width of the comb tooth portion 422A of the first air vent 42A is 2 mm to 4 mm as described above, human fingertips are kept from entering the gap 600 from the first air vent 42A. The first air vent 42A can thus prevent human fingers from touching the terminal 405 (bolt 300) of the relay 400 or the bus bar 500 while allowing airflow inside and outside of the cover member 40.

The same parts as those in Embodiment 1 are given the same reference signs and their detailed description is omitted.

Embodiments 1 to 4 disclosed herein are illustrative and not restrictive in all respects. The scope of the present disclosure is defined by the claims, and not the meaning described above, and is intended to include all modifications within the meaning and scope equivalent to the claims.

The matters described in Embodiments 1 to 4 can be combined with each other. The independent claims and dependent claims described in the claims can be combined with each other in any way regardless of the form of reference. Although a format in which a claim refers to two or more other claims (multi-claim format) is used in the claims, there is no limitation to this. A format in which a multi-claim refers to at least one multi-claim (multi-multi-claim format) may be used in the claims.

1. An electrical junction box comprising:
a housing containing an electronic component that generates heat when energized; and
a cover member that covers a terminal provided on a side surface of the electronic component, and that covers a surrounding area of the terminal,
wherein the cover member has an air vent that allows airflow inside and outside of the cover member.

2. The electrical junction box according to claim 1,
wherein the electronic component is mounted on a pedestal provided in the housing,
the cover member includes a facing plate that faces the side surface of the electronic component, and an electric shock prevention plate that is provided at an edge of the facing plate located apart from the housing and shields a gap between the facing plate and the side surface to prevent electric shock, and
the air vent includes a first air vent formed in the electric shock prevention plate.

3. The electrical junction box according to claim 2, wherein the first air vent is formed at one edge of the electric shock prevention plate closer to the side surface of the electronic component.

4. The electrical junction box according to claim 3, wherein the air vent includes a second air vent formed in the electric shock prevention plate apart from the one edge.

5. The electrical junction box according to claim 3, wherein the first air vent has a comb shape that is open toward another edge opposite to the one edge.

6. The electrical junction box according to claim 2, wherein the air vent includes a third air vent formed in the facing plate.

7. The electrical junction box according to claim 2,
wherein the pedestal includes a clamping mechanism that clamps the facing plate, and
the facing plate has an engagement protrusion that engages with an engagement portion formed in the clamping mechanism.

8. The electrical junction box according to claim 4, wherein the first air vent has a comb shape that is open toward another edge opposite to the one edge.

9. The electrical junction box according to claim 3, wherein the air vent includes a third air vent formed in the facing plate.

10. The electrical junction box according claim 4, wherein the air vent includes a third air vent formed in the facing plate.

11. The electrical junction box according to claim 3,
wherein the pedestal includes a clamping mechanism that clamps the facing plate, and
the facing plate has an engagement protrusion that engages with an engagement portion formed in the clamping mechanism.

12. The electrical junction box according to claim 4,
wherein the pedestal includes a clamping mechanism that clamps the facing plate, and
the facing plate has an engagement protrusion that engages with an engagement portion formed in the clamping mechanism.
